(19) United States
(12) Patent Application Publication
(10) Pub. No.: US 2011/0030773 A1
(43) Pub. Date: Feb. 10, 2011

(54) PHOTOVOLTAIC CELL WITH BACK-SURFACE REFLECTIVITY SCATTERING

(75) Inventors: HOWARD M. BRANZ, Golden, CO (US); Charles Teplin, Golden, CO (US); Pauls Stradins, Golden, CO (US)

Correspondence Address: PAUL J WHITE, Assoc. General Counsel;NATIONAL RENEWABLE ENERGY LABORATORY (NREL), 1617 COLE BOULEVARD, MS 1734, GOLDEN, CO, 80401-3393, US

(73) Assignee: ALLIANCE FOR SUSTAINABLE ENERGY, LLC, GOLDEN, CO (US)

(21) Appl. No.: 12/537,185

(22) Filed: Aug. 6, 2009

(51) Int. Cl. H01L 31/00; H01L 21/30

(52) U.S. Cl. 136/256; 438/72; 257/E21.211

(57) ABSTRACT

Crystal oriented photovoltaic cells with increased efficiency are disclosed herein. In an exemplary embodiment, a photovoltaic device includes a metal substrate with a crystalline orientation comprising a diffracting structure integrated into a surface of the metal substrate. The photovoltaic device includes a heteroepitaxial crystal silicon layer having the crystalline orientation of the metal substrate and a heteroepitaxially grown buffer layer having the crystalline orientation. The buffer layer is positioned adjacent to the surface of the metal substrate having the diffracting structure.

The United States Government has rights in this invention under Contract No. DE-AC36-08GO28308 between the United States Department of Energy and the National Renewable Energy Laboratory, managed and operated by the Alliance for Sustainable Energy, LLC.

### BACKGROUND

Photovoltaic cells, sometimes referred to as “solar cells,” convert sunlight into electricity. Photovoltaic cells are made of multiple layers of semiconductor material, such as silicon. When sunlight or other light energy strikes a photovoltaic cell, photons excite electrons in the semiconductor material to a higher energy state and liberate electrons from their bonding energy levels, thereby producing transporting electron charge carriers and transporting hole carriers in the vacated energy levels. Typically, the liberated electrons flow in one direction through the semiconductor material and holes flow in the opposite direction to a different layer of semiconductor material. Much like a typical battery with a positive and negative contact, in order to use the generated electricity, a first contact or set of contacts are coupled to the layer or layers of the semiconductor material collecting electrons and a second contact or set of contacts are coupled to the layer or layers of semiconductor material collecting holes to extract the electrons and holes at their respective potential energy levels.

The foregoing examples of the related art and limitations related therewith are intended to be illustrative and not exclusive. Other limitations of the related art will become apparent to those of skill in the art upon a reading of the specification and a study of the drawings.

### SUMMARY

The following embodiments and aspects thereof are described and illustrated in conjunction with systems, tools and methods which are meant to be examples and illustrative, not limiting in scope. In various embodiments, one or more of the above-described problems have been reduced or eliminated, while other embodiments, are directed to other improvements.

In one embodiment, a photovoltaic device includes a metal substrate with a crystalline orientation comprising a diffracting structure integrated into a surface of the metal substrate. Additionally, the photovoltaic device may include a heteroepitaxial crystal silicon layer having the crystalline orientation of the metal substrate and a heteroepitaxially grown buffer layer having the crystalline orientation. The buffer layer is positioned adjacent to the surface of the metal substrate having the diffracting structure.

In another embodiment, a solar cell is disclosed having a nickel tungsten substrate with a crystalline orientation and a heteroepitaxially grown buffer layer having the crystalline orientation. Additionally, the solar cell includes a metal layer positioned between the buffer layer and the substrate, the metal layer comprising a metal having a higher reflectivity than nickel. Moreover, the cell includes a heteroepitaxial crystal silicon layer grown over the buffer, the crystal silicon having the crystalline orientation of the metal substrate.

In another embodiment, a method for increasing back surface reflectivity of a photovoltaic cell is disclosed. The method includes forming a 2-10 nanometer reflective layer over a metal substrate, the reflective layer having a higher reflectivity than the metal of the metal substrate. Additionally, the method includes heteroepitaxially growing a buffer layer and crystal silicon layer. The buffer layer is located between the reflective layer and the crystal silicon layer and each of the metal substrate, reflective layer, buffer layer and crystal silicon layer has a common crystal orientation.

In another embodiment, a photovoltaic cell is disclosed that has a nickel tungsten substrate with a crystalline orientation comprising a rough topography surface. The photovoltaic cell also includes a heteroepitaxial crystal silicon layer having the crystalline orientation of the metal substrate and a heteroepitaxially grown buffer layer having the crystalline orientation. The buffer layer is positioned between the crystal silicon layer and the substrate.

In addition to the various examples and embodiments described above, further aspects and embodiments will become apparent by reference to the drawings and by study of the following descriptions.

### BRIEF DESCRIPTION OF THE DETAILED DRAWINGS

Example embodiments are illustrated in referenced figures of the drawings. It is intended that the embodiments and figures disclosed herein are to be considered illustrative rather than limiting.

FIG. 1 illustrates a cross-sectional view of an exemplary crystal silicon structure heteroepitaxially grown over a buffer covered metal substrate.

FIGS. 2A-2E illustrate exemplary epitaxially-grown layers for photovoltaic cell fabrication having a metal layer formed over a crystal oriented substrate and a corresponding flowchart of a related process.

FIGS. 3 and 4 graphically illustrate a portion of the solar spectrum that can be absorbed by a 5 micron thick C—Si example solar cell using either nickel or silver as the back substrate.

FIGS. 5A-5D illustrate exemplary epitaxially-grown layers for photovoltaic device fabrication with a rough topography substrate and a corresponding flowchart for a related process.

FIGS. 6A-C illustrate embodiments of a photovoltaic cell with diffracting structures integrated into a metal substrate and a flowchart of a related process.

FIGS. 7A-7D illustrate an embodiment of a photovoltaic cell implementing a combination of the techniques disclosed herein and a flowchart for a related process.

### DESCRIPTION

Various embodiments and processes described herein set forth exemplary photovoltaic cells and processes that provide reflectivity for increasing light-trapping properties of a photovoltaic cell having heteroepitaxially grown silicon on crystal oriented, buffer covered metal substrates. In one example, a metal layer having a higher reflectivity than the metal substrate is provided to reflect light back through silicon layers of the photovoltaic cell. Hence, light that passed through the silicon layers and was not absorbed to generate a flow of electrons and holes, may reflect back into the silicon layers and be absorbed in the second pass. In another example, a rough, patterned, and otherwise non-smooth surface topography may be created on the metal substrate, which whether employed alone or in conjunction with a reflection layer, may reflect photons that have passed through the silicon layers, where the photovoltaic effect occurs, and provide a second pass for the photons to be absorbed. Additionally, the non-smooth surface may angularly reflect the photons through the silicon layers, causing the photons to pass through a greater portion of the silicon layers then when the photons enter the silicon layers approximately perpendicular to the surface of the cell.

Although brief descriptions of the various steps generally involved in forming a heteroepitaxially grown semiconductor layer over a buffer covered metal substrate are included herein, PCT Patent Application No. PCT/US09/33937, entitled, “Crystal Silicon Processes and Products,” (NREL PCT/08-80) filed on Feb. 12, 2009, is incorporated herein by reference in its entirety and for all purposes, and may be referred to for additional information regarding the process of heteroepitaxially growing a semiconductor material over a metal substrate.

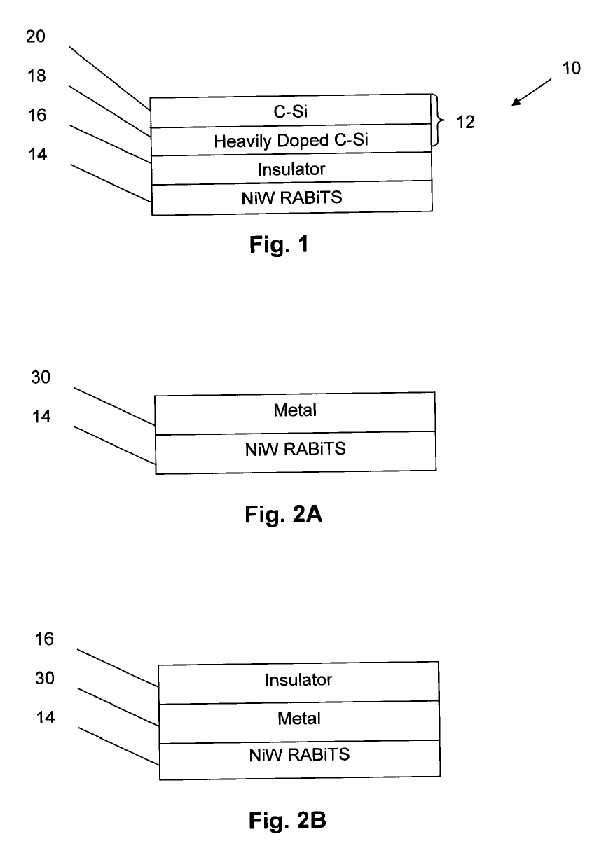

Turning to the figures and referring initially to FIG. 1, a representative cross-section of one example of several layers of a photovoltaic cell 10 having crystal silicon layers 12 heteroepitaxially grown over an insulating buffer 16 covered crystalline metal substrate 14 is illustrated. The total thickness of the crystal silicon layer 12 may be between approximately 2 and 10 micrometers thick. The crystal silicon layer 12 may act as absorber layers (photovoltaic effect layers) to absorb photons that strike the photovoltaic cell 10. The metal substrate 14 may be between approximately 20 to 200 microns thick and made of one or more metals, alloys or other materials. In one particular implementation, the metal substrate is made of nickel-tungsten (NiW). For the purposes of this discussion, the metal substrate 14 may be referred to as the NiW substrate, NiW layer, metal substrate, metal layer, substrate, or other suitable term.

It should be appreciated that illustration of FIG. 1 and all other figures presented herewith do not represent an accurate scale for the features shown therein. Thus, the illustrations contained in the figures are to be understood as being exemplary and not necessarily representative of actual or relative sizes and shapes of the illustrated features.

The metal substrate 14 may be fabricated in part through a process referred to as “RABiTS” (rolling assisted biaxially textured substrates) that imparts a biaxial orientation in the metal substrate. In other embodiments, the metal substrate 14 may have other crystalline orientations, such as uniaxial orientation, for example. Hence, the metal substrate 14 has a well-organized, consistent biaxially, uniaxially, or otherwise oriented crystalline structure. The biaxial orientation of the substrate 14 may serve as a template for other layers formed over the metal substrate 14. Hence, one or more layers of the photovoltaic cell 10 may have a common orientation. The orientation may increase the overall efficiency of the photovoltaic cell 10 by decreasing the number of defects through the photovoltaic cell structure and thereby reducing the occurrence of electron/hole recombination that reduces the useful generation of power from the device.

After the metal substrate 14 is textured, one or more buffer layers 16 may be heteroepitaxially grown on the metal substrate 14. Through heteroepitaxy, different material (from the substrate) layers are fabricated that have the same texture (e.g., biaxial) as the substrate 14. For example, as illustrated, the metal substrate 14 may be covered with an insulating buffer layer 16 made of magnesium oxide (MgO) and gamma-aluminum oxide (Al₂O₃). Other materials may also be used to form the buffer 16. The insulating buffer 16 may be between approximately 20 and 500 nanometers thick. While only one buffer layer is shown, additional buffer layers or other layers, such as a reflective layer, are also possible.

Among other things, the buffer layer 16 may prevent diffusion of metal atoms from the metal substrate 14 into the crystal silicon layers 12. For example, the buffer layer 16 may prevent diffusion of nickel and/or tungsten from the metal substrate 14 into the silicon layers 12 during epitaxial growth of the silicon layers 12. Epitaxial growth may involve temperatures between about 620 to 800 degrees Celsius over a time of about 10-50 minutes. Without a buffer layer, nickel, for example, can be expected to diffuse one micron into the silicon layer in 20 minutes at 800 degrees Celsius. Nickel is an efficient electron-hole pair recombination center in silicon and hence such diffusion would impair the function of the cell. Alternatively, the diffusion of the nickel into the silicon layer may lead to shunting of the semiconductor material of the photovoltaic cell 10 through conductive nickel silicide pathways. In addition to reducing or eliminating any diffusion or adverse effects of diffusion of the metal substrate 14, the buffer layer 16 may also provide a chemically compatible surface for the growth of the silicon layers 12.

Once the buffer layer 16 is formed, one or more layers 12 of crystal silicon may be heteroepitaxially grown over the buffer layer 16 to form an absorber region of the photovoltaic cell 10. The absorber region generally may refer to the semiconductor material in a photovoltaic cell, as the semiconductor material absorbs photons (through electron excitement and displacement) to generate electrical potential. In the particular example shown in FIG. 1, a first crystal silicon layer 18 is heteroepitaxially grown on the buffer layer 16. The first crystal silicon layer 18 may be doped with an atom foreign to the silicon, such as boron, phosphorus, arsenic, or gallium, for example, to create a charged n+ or p+ region. For example, the first silicon layer 18 may be doped with phosphorus to form an n+ region to facilitate the flow of electrons in the direction of the buffer layer when photons strike the photovoltaic cell 10. Moreover, the highly doped first crystal silicon layer 18 may also act as a high lateral conducting semiconductor layer that allows electrons or holes to migrate to electrical contact points in layer 18.

Additional crystal silicon layers 20 may be heteroepitaxially grown over the first crystal silicon layer 18. The additional layers 20 may or may not be doped in order to facilitate the flow of electrons or holes toward the top of the photovoltaic cell where a top contact (not shown) may be located. Indeed, the additional layers may include undoped crystal silicon layer(s), lightly doped crystal silicon layer(s), heavily doped crystal silicon layer(s), a crystal silicon emitter, and/or an amorphous silicon heterojunction emitter. Each of the crystal silicon layers 12 may have the same crystal orientation as the metal substrate 14. For example, if the metal substrate 14 has a biaxial orientation, the first crystal silicon layer 18, the second crystal silicon layer 20, and any other layers would have the same biaxial orientation.

It should be understood that the additional crystal silicon layers 20 may include layers that are doped to have an opposite charge from the highly doped layer 18. Hence, a p−n junction (not shown) is formed in the additional crystal silicon layers 20. As such, the simplified representation of the photovoltaic cells in the drawings and as described herein is intended to help facilitate understanding of the concepts discussed herein but not intended to include all the features and details that may be included in an actual implementation of a photovoltaic cell which would be understood by those skilled in the art of photovoltaic cells.

In one implementation, the substrate may be employed as a contact. In such an implementation as well as other possible implementations, conduction pathways may be formed through the buffer layer to provide a path for electron or hole migration between the silicon layers and the metal substrate. Various structures and methods for providing such conductive pathways are described in “Back Contact to Film Silicon on Metal for Photovoltaic Cells”, U.S. Ser. No. 12/537,152, docket number NREL 08-56, which is hereby incorporated by reference herein.

As previously mentioned, the crystal silicon layers 12 may be only a few microns thick. Because of the thinness of the silicon layers 12 some wavelengths are not absorbed well by the silicon layers 12. For example, much of the red and infrared light simply passes through the silicon layers 12. In particular, wavelengths between 550 and 900 nanometers should be reflected back into crystal silicon absorber layers to increase absorption and, hence, efficiency of the cell. Light-trapping techniques may be implemented to help the photovoltaic cell 10 absorb more of the red and infrared light, as well as light of other wavelengths.

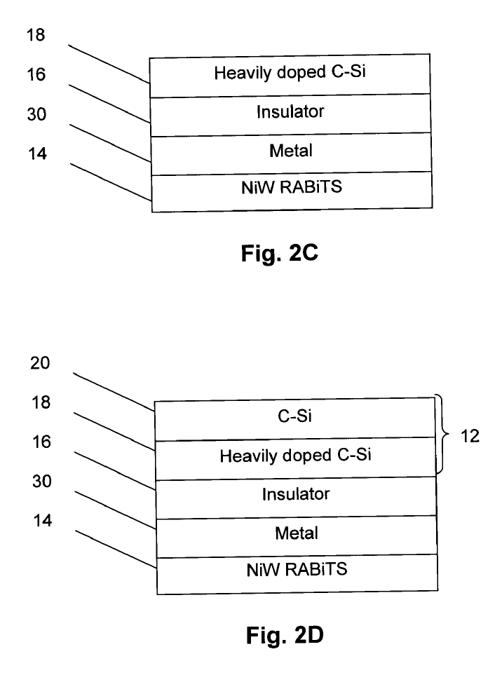

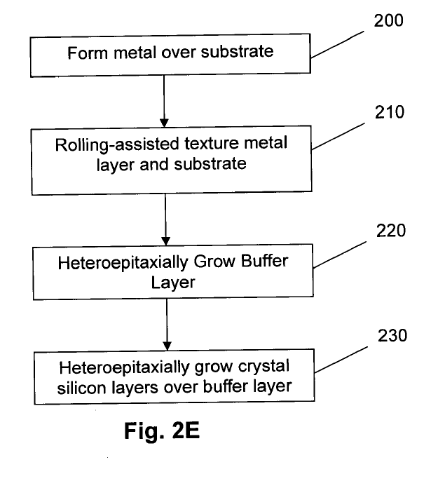

In one embodiment, the reflectivity from the metal foil substrate is increased by coating the NiW substrate 14 with another metal before heteroepitxailly growing a buffer layer, such as MgO or other textured buffer layers. FIGS. 2A-2E and the flowchart of FIG. 2F illustrate the structure and process for coating the NiW substrate 14 with another metal. Referring initially to FIG. 2A, a metal layer 30 is formed over the NiW substrate 14 (operation 200, FIG. 2F). The metal layer 30 may be approximately 2-10 nanometers thick or thicker. For example, the metal layer 30 may be between 10-30 nanometers thick or any other thickness suitable for a particular application.

The metal used for the metal layer 14 should be more reflective than the nickel of the NiW substrate 14. Metals that have a higher reflectivity than nickel, and which may be candidates for use in the metal layer 30, include aluminum (Al), gold (Au), silver (Ag), copper (Cu), and rhodium (Rh), for example. In selecting a particular metal for use in the metal layer 30, several factors may be considered, such as, the stability of the thin layer, ability of the layer to reproduce the RABiTS biaxial orientation, reflectivity, and low diffusion co-efficient of the material into the buffer layers at temperatures up to 800 degrees Celsius for the process of growing silicon crystals. Because of the possibility of diffusion of the metal into the crystal silicon layers 12, a metal that is more benign in silicon, for example aluminum, may be used.

The metal layer 30 may be textured using the RABiTS process so that it has the same crystal orientation as the NiW substrate 14. In one embodiment, the metal layer 30 and the substrate 14 are textured concurrently (operation 210). In other embodiments, the substrate 14 may be textured before formation of the metal layer 30. The crystalline texture (orientation) of the NiW substrate 14 allows for uniaxially or biaxially textured silicon to be grown.

Once the reflective metal layer 30 is formed, the other layers of the photovoltaic cell 10 may be formed. As shown in FIG. 2B, the buffer layer 16 may be heteroepitaxially grown adjacent to the metal layer 30 (operation 220). Thereafter, crystal silicon layers 12 may be grown (operation 230). Specifically, as shown in FIG. 2C, the first crystal silicon layer 18 may be grown and subsequently additional crystal silicon layers 20 may be heteroepitaxially grown, as shown in FIG. 2D, to form absorber layers of a photovoltaic cell 32 that has a highly reflective back surface. Each layer of the photovoltaic cell 32 has the same crystalline orientation, similar to the photovoltaic cell 10 of FIG. 1.

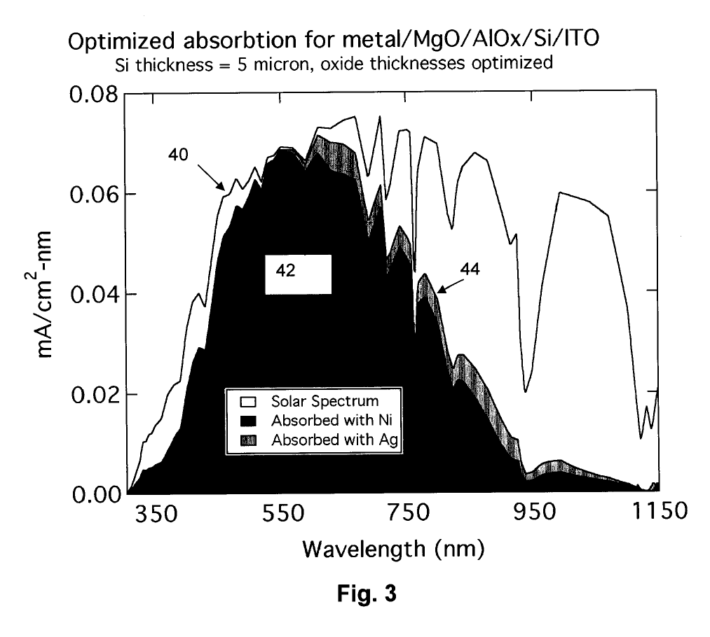

An exemplary optical simulation of a planer structure with 5 microns of silicon on Al₂O₃/MgO/metal shows an increase of about 1-2 mA/cm² in short-circuit current availability for a solar cell with a silver reflective back surface, compared to the nickel substrate back. Specifically, FIG. 3 illustrates a plot 40 of the simulation. As illustrated, the horizontal axis is the thickness of the silicon in micrometers and the vertical axis is the device current in mA/cm². As can be seen, a line 42 representative of the current generated in the silicon when nickel serves as a reflective surface is approximately 1-2 mA/cm² lower than the line 44 representing the current generated when silver is used as the reflective surface. The simulation demonstrates the possible effectiveness of applying the metal layer 30 to increase the efficiency of the photovoltaic cell. Most of the improvement occurs at wavelengths above 550 nanometers, where silicon is less absorbing.

In addition to or without providing the reflective metal layer 30, the thickness of the buffer layer 16, the composition of the buffer layer, and combinations of buffer layer material, may influence the efficiency of photovoltaic cells, such as those illustrated in FIGS. 1 and 2D. Specifically, the choice of a correct thickness of the insulating buffer layers 16 between the metal substrate 14 and the crystal silicon layers 12 can improve the reflectivity from a back surface. Optical simulation of available current from a planer photovoltaic structure, i.e. a photovoltaic cell without topographical surface variations in the layers, which are discussed below, with about 10 nm of magnesium oxide between aluminum oxide and the metal substrate 14 suggests that the aluminum oxide has an optimum thickness of about 74 nm for a nickel backing surface. The choice of layer thicknesses will depend on the actual optical properties of the layers. If other surfaces, such as silver for example, are used, the thickness may also vary. Additionally, if the magnesium oxide layer is not 10 nm thick, the optimal thickness of the aluminum oxide may vary.

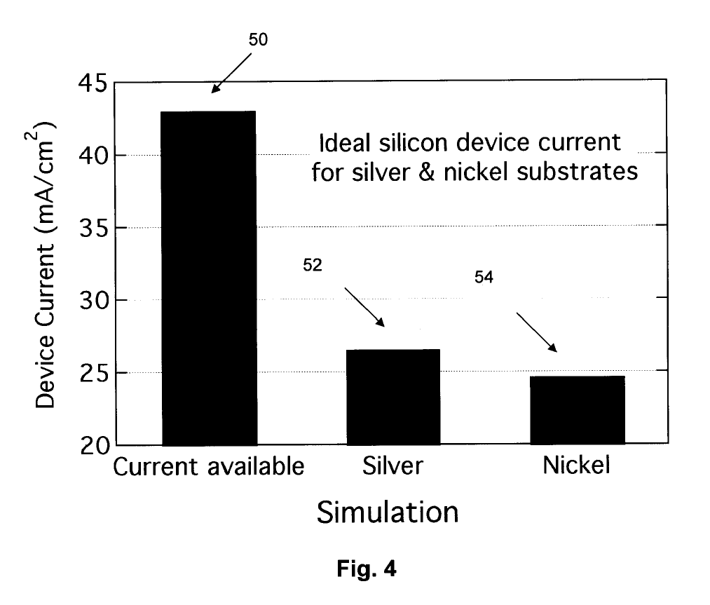

FIGS. 3 and 4 graphically illustrate a portion of the solar spectrum that can be absorbed by solar cells using either nickel or silver as the back substrate. In FIG. 3, the horizontal axis represents wavelengths of light in nanometers and the vertical axis represents a portion of the solar spectrum that is absorbed in different devices (expressed in mA/cm², where it is assumed that each photon from sunlight creates on electron-hole pair). The plot line 40 indicates the total spectrum available to a perfect device. Plot line 42 indicates absorbed sunlight for a device with a nickel (Ni) substrate and plot line 44 indicates the absorbed sunlight for a device with a silver (Ag) substrate. As can be seen, great improvement potential is available for portions of the solar spectrum between 550 nm and 1150 nm. The total current for each case is indicated in FIG. 4. In FIG. 4, the vertical axis indicates the total current produced by various device simulations. Bar 50 is the current created by a silicon device where all of the solar spectrum above the silicon bandgap is absorbed. Plot bar 52 is the current produced by a silicon device fabricated on silver and plot bar 54 is the current produced by a silicon device fabricated on nickel. As can be seen, the silver provides for greater absorption and current generation relative to nickel. Together, FIGS. 3 and 4 show that higher currents and, therefore, more efficient devices, can be obtained from silicon photovoltaic devices fabricated on silver instead of nickel.

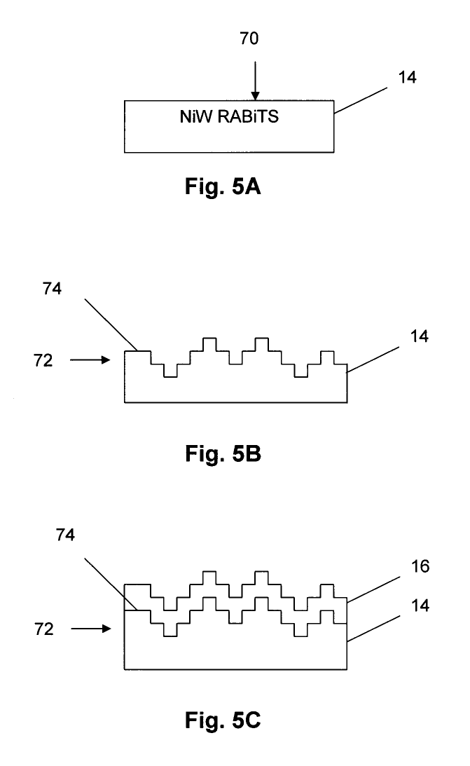

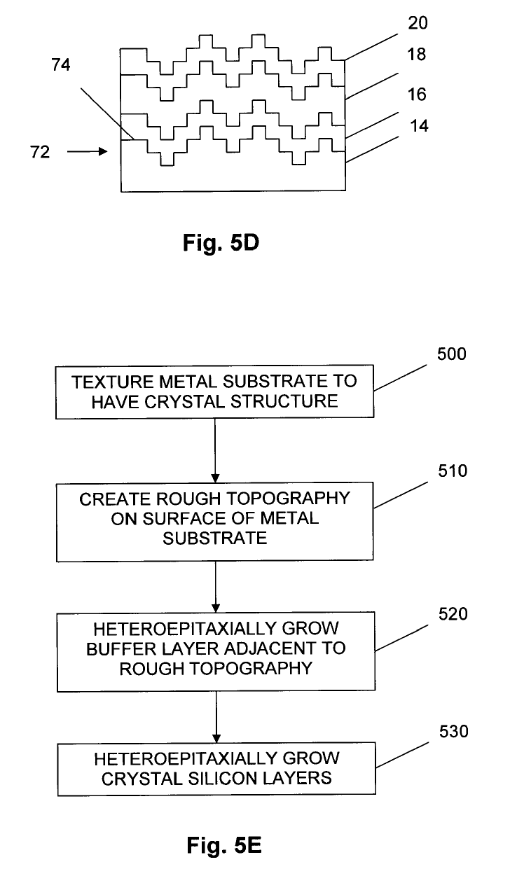

The foregoing embodiments present planer structures for increasing the efficiency of a photovoltaic cell. However, in other embodiments, the efficiency may be increased by implementing non-planer structures, alone or in conjunction with additional reflection surfaces. For example, in another embodiment, a rough surface topography may be integrated with the NiW substrate 14 to scatter and reflect light that passes through the crystal silicon layers 12 without being initially absorbed. FIGS. 5A-D and the corresponding flowchart of FIG. 5E illustrate the general structure and process for implementing the rough surface topography.

In FIG. 5A, the NiW substrate 14 is shown having a planer surface 70. The NiW substrate has a texture to provide the substrate 14 with a crystalline orientation (operation 500, FIG. 5E). The RABiTS process typically produces relatively flat and smooth planar surfaces. The surface 70 of the NiW substrate 14 may be roughened to provide a rough non-planar topography 72, illustrated in FIG. 5B (operation 510). The rough topography 70 may have a random pattern with various peaks and valleys, as shown. In particular, the topography includes horizontal surfaces at different heights with steps in between them. The peaks may be between about 300 nanometers and 2 micrometers high. In other embodiments, the non-planar topography may have a unified pattern, such as a repeating pattern, for example, that may be a result of the process used to generate the rough topography.

For example, the rough topography 72 may be created by embossing the surface 70 of the NiW substrate 14 at the end of rolling. The embossing process may include embossing a particular pattern into the substrate 14 through one or more passes of an embossing mechanism. In other embodiments, the rough topography 72 may be created by mechanical roughening, chemical etching, laser etching or chemo-optical etching with laser induced chemical etch, or other suitable technique, each of which may be used to create a random pattern or a repeating pattern on the substrate surface.

Care should be taken during the etching or embossing to preserve the crystal orientation of the NiW substrate 14 so that the crystal structure may be a template for subsequent layer growth. To aid in preserving the crystal structure of the substrate 14, a hot roughening or an anneal after roughening may be appropriate. For example, an annealing step in vacuum at about 700° C. for about 60 minutes (or other suitable time and temperature combinations) may help to improve the crystal structure at the surface of the substrate for subsequent layer growth.

Once the rough topography 70 is created, the buffer layer 16 may be heteroepitaxially grown, as shown in FIG. 5C. The buffer layer 16 is grown over the rough topography (operation 520). The crystal silicon layers 12 may then be heteroepitaxially grown, as illustrated in FIG. 5D (operation 530).

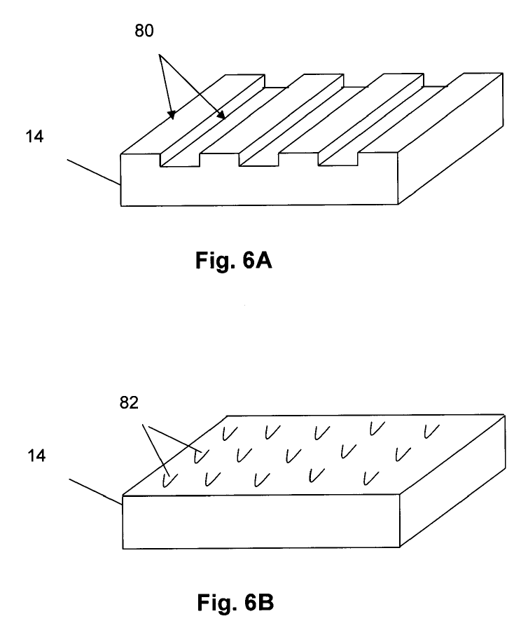

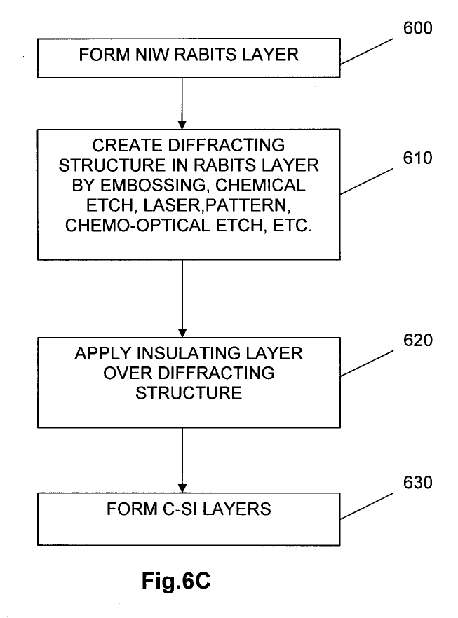

Other treatments to the surface 70 of the metal substrate 14 may provide increased efficiency in a photovoltaic cell. For example, as illustrated in FIGS. 6A-6B and the flowchart of FIG. 6C, in other embodiments, a diffracting structure may be integrated into the surface of the NiW substrate 14 to enhance path lengths of reflected wavelengths in the silicon layers 12 after formation and orientation of the NiW substrate (operation 600). In one embodiment, illustrated in FIG. 6A, a diffracting array 80 of geometric shapes may be created in the surface 70 of the metal substrate 14 (operation 610). As illustrated, the array 80 may include lines embedded in the NiW substrate 14 to form a grating structure. In an embodiment, a diffracting array 82 may include dots, as shown in FIG. 6B (operation 610). The dots may be concave relative to the surface 70 of the substrate 14. Other diffracting structures (not shown) may also be created to perform the same or a similar function as the lines 80 and the dots 82. The diffracting lines 80 or dots 82 may be between 100-1000 nm deep and spaced between 300-600 nm apart.

As with the rough topography of FIG. 5B, the diffracting array structures 80 or 82 may be introduced by embossing, laser etching, laser-chemical etching, etc. (operation 610). Again, care should be taken not to disturb the crystal structure of the RABiTS layer and the embossing or etching may be performed at a high temperature and/or an anneal process may be performed after forming the diffracting structures may aid in preserving the crystal orientation. Once the diffracting structure (80 or 82) is created, the additional layers may be grown. Specifically, the buffer layer may be grown (operation 620) and the crystal silicon layers may be grown (operation 630), as discussed in detail above.

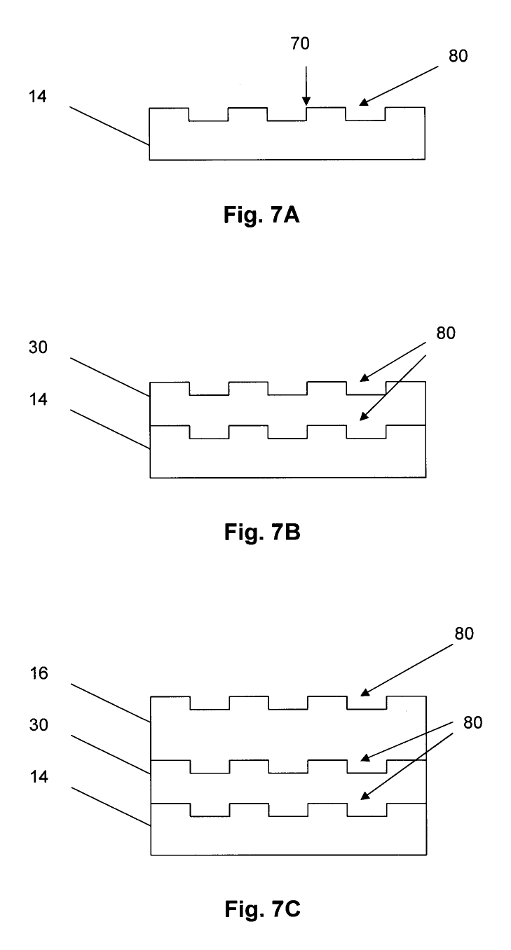

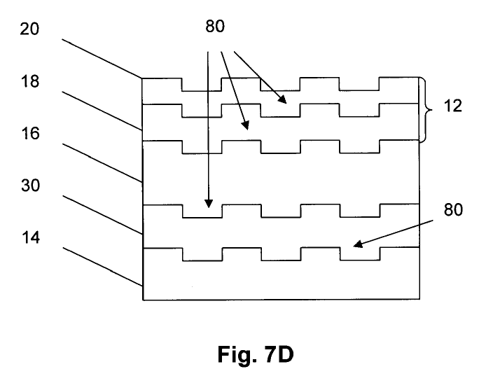

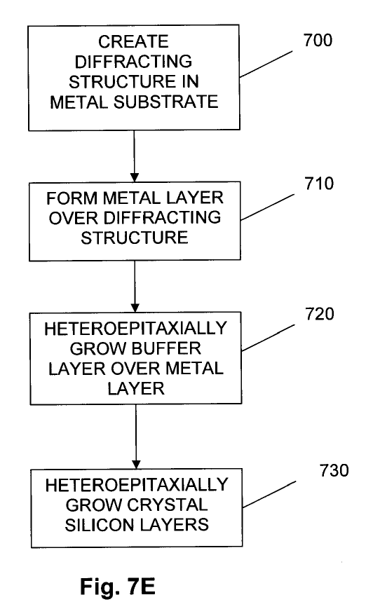

Each of the various embodiments discussed above may be implemented alone or in combination with any of the other embodiments to further enhance the efficiency of a photovoltaic cell by increasing the reflectivity of the back surface in the photovoltaic cell. For example, FIGS. 7A-7E illustrate an example combination of the embodiment and a flowchart illustrating the related process. Beginning with FIG. 7A, a NiW substrate 14 is illustrated as having a diffracting structure 80 integrated into a top surface 70 of the NiW substrate 14 (operation 700). A metal layer 30 may be formed over the diffracting structure 80 (FIG. 7B, operation 710). The metal layer 30 may include metal having a higher reflectivity than nickel. The buffer layer 16, having a thickness of approximately 74 nanometers, may then be heteroepitaxially grown (FIG. 7C; operation 720) and, subsequently, the crystal silicon layers 12 may be grown (FIG. 7D; operation 730). The metal layer 30 and the subsequent layers (i.e., buffer layer 16, crystal silicon layers have the same layered structure as exists in the RABiTS substrate 14, as illustrated.

While a number of example aspects and embodiments have been discussed above, those of skill in the art will recognize certain modifications, permutations, additions and sub combinations thereof. It is therefore intended that the following appended claims and claims hereafter introduced are interpreted to include all such modifications, permutations, additions and sub-combinations as are within their true spirit and scope.

1. A photovoltaic device comprising:
a metal substrate with a crystalline orientation comprising a diffracting structure integrated into a surface of the metal substrate;
a heteroepitaxial crystal silicon layer having the crystalline orientation of the metal substrate; and
a heteroepitaxially grown buffer layer having the crystalline orientation, the buffer layer positioned adjacent to the surface of the metal substrate having the diffracting structure.

2. The photovoltaic device of claim 1 wherein the diffracting structure comprises an array of lines spaced between about 300 and 600 nanometers apart.

3. The photovoltaic device of claim 2 wherein the lines form channels between about 100 and 1000 nm into the surface.

4. The photovoltaic device of claim 1 wherein the diffracting structure comprises an array of depressions in the metal substrate, the depressions spaced between about 300 and 600 nanometers apart.

5. The photovoltaic device of claim 4 wherein the depressions of the array are between about 100 and 1000 nm deep.

6. The photovoltaic device of claim 1 comprising a metal layer positioned between the buffer layer and the metal substrate.

7. The photovoltaic device of claim 6 wherein the metal layer comprises at least one of gold, silver, aluminum, copper, and rhodium.

8. The photovoltaic device of claim 1 wherein the metal layer is between about 2 and 10 nanometers thick.

9. The photovoltaic device of claim 1 wherein the buffer layer is approximately 74 nm thick.

10. The photovoltaic device of claim 1 wherein:
the metal substrate comprises a nickel tungsten foil textured by a rolling assisted process, the crystal orientation being a biaxial orientation; and
the buffer layer comprises magnesium oxide and aluminum oxide.

11. A solar cell comprising:
a nickel tungsten substrate with a crystalline orientation;
a heteroepitaxially grown buffer layer having the crystalline orientation;
a metal layer positioned between the buffer layer and the substrate, the metal layer comprising a metal having a higher reflectivity than nickel; and
a heteroepitaxial crystal silicon layer grown over the buffer, the crystal silicon having the crystalline orientation of the metal substrate.

12. The solar cell of claim 11, wherein the metal layer comprises at least one of gold, silver, aluminum, copper and rhodium.

13. The solar cell of claim 12 wherein the metal layer is between about 2 and 10 nanometers thick.

14. The solar cell of claim 11 wherein the nickel tungsten substrate comprises a non-planar topography surface adjacent the metal layer.

15. The solar cell of claim 11 wherein the nickel tungsten substrate comprises a diffracting structure integrated in a surface adjacent the metal layer.

16. The solar cell of claim 15 wherein the diffracting structure comprises an array of substantially linear channels about 100 to 1000 nanometers deep and about 300-600 nanometers apart.

17. The solar cell of claim 15 wherein the diffracting structure comprises an array of dots about 100 to 1000 nanometers deep and about 300-600 nanometers apart.

18. The solar cell of claim 15 wherein the buffer layer comprises an approximately 10 nanometer thick magnesium oxide buffer layer and an aluminum oxide buffer layer that is approximately 74 nanometers thick.

19. A method for increasing back surface reflectivity of a photovoltaic cell comprising:
forming an approximately 2-10 nanometer reflective layer over a metal substrate, the reflective layer having a higher reflectivity than the metal of the metal substrate;
heteroepitaxially growing a buffer layer and a crystal silicon layer, the buffer layer being located between the reflective layer and the crystal silicon layer, wherein each of the metal substrate, buffer layer and crystal silicon layer has a common crystal orientation.

20. The method of claim 19 comprising forming a rough topography on a surface of the metal substrate adjacent the reflective layer, wherein the rough topography is formed by one of embossing, mechanical roughening, chemical etching, laser etching and chemo-optical etching.

21. The method of claim 19 comprising forming a diffracting structure on a surface of the metal substrate adjacent the reflective layer, wherein the diffracting structure is formed by one of embossing, mechanical roughening, chemical etching, laser etching and chemo-optical etching.

22. A photovoltaic cell comprising:
a nickel tungsten substrate with a crystalline orientation comprising a rough topography surface;
a heteroepitaxial crystal silicon layer having the crystalline orientation of the metal substrate; and
a heteroepitaxially grown buffer layer having the crystalline orientation, the buffer layer being positioned between the crystal silicon layer and the substrate.

23. The photovoltaic cell of claim 22 further comprising a metal layer about 2 to 10 nanometers thick positioned between the rough topography surface and the buffer layer, wherein the metal layer comprises at least one of gold, silver, copper, aluminum, and rhodium;
and wherein the rough topography includes peaks approximately 300 nanometers to 2 micrometers above the surface of the substrate, and wherein the buffer layer comprises a plurality of conductive pathways to provide electron or hole migration from the silicon layer to the nickel tungsten substrate.
